(19) United States
(12) Patent Application Publication
(10) Pub. No.: US 2013/0094161 A1
(43) Pub. Date: Apr. 18, 2013

(54) MOBILE WIRELESS DEVICE

(71) Applicants: Takahiro Ochi, Miyagi (JP); Kouta Aoki, Kanagawa (JP); Akito Sakamoto, Kanagawa (JP); Kenshi Horihata, Kanagawa (JP); Masashi Koshi, Ishikawa (JP)

(72) Inventors: Takahiro Ochi, Miyagi (JP); Kouta Aoki, Kanagawa (JP); Akito Sakamoto, Kanagawa (JP); Kenshi Horihata, Kanagawa (JP); Masashi Koshi, Ishikawa (JP)

(73) Assignee: PANASONIC CORPORATION, Osaka (JP)

(21) Appl. No.: 13/704,948

(22) PCT Filed: Jul. 5, 2011
(86) PCT No.: PCT/JP2011/003842

§ 371 Date: Dec. 17, 2012

(30) Foreign Application Priority Data
Jul. 5, 2010 (JP) 2010-153435

(51) Int. Cl. H05K 5/02

(52) U.S. Cl. CPC H05K 5/0226
USPC 361/752

(57) ABSTRACT

A mobile wireless device includes a first housing, a second housing, a first hinge configured to freely openably and closably connect the first housing with the second housing, a first circuit board provided in the first housing, a second circuit board provided in the second housing, a signal cable configured to electrically connect the first circuit board with the second circuit board, a plate-shaped ground that is provided so as to be stacked on the second circuit board and has a notch at a location through which the signal cable is passed, and a conductive member that covers the signal cable and the notch.

### TECHNICAL FIELD

The invention relates to a foldable mobile wireless device.

### BACKGROUND ART

In such foldable mobile wireless devices, a device is known in which two housings each having a circuit board, and these two circuit boards are connected to each other via a signal cable (e.g., see Patent Documents 1 and 2). In particular, in a mobile wireless device disclosed in Patent Document 1, a ground (typically, a shielded wire) exposed by peeling a sheath of the signal cable in a vicinity of a hinge in each of the housings is connected to a ground of each of the circuit boards, to prevent deterioration in antenna performance due to an extended routing length of the signal cable for connecting two circuit boards to each other.

Also, in the foldable mobile wireless devices, a device is known in which a two-axis rotation structure (also referred as a “swivel structure”) is employed to take a closed state upon standby, an opened state upon making a call, and a viewer state closed to allow a screen to be seen upon watching a television broadcasting (frequently, a one-segment broadcasting). FIG. 14 shows perspective views of the exterior of a foldable mobile wireless 100 device employing such a two-axis rotation structure. In this figure, FIG. 14(a) shows a vertical opened state and FIG. 14 (b) shows a state in that a second housing is also vertically opened but rotated by approximately 90 degrees. The mobile wireless device 100 includes three housings (i.e., a first housing 101, a second housing 102, and a third housing 103), the first housing 101 and the third housing 103 are freely openably and closably connected to each other via a first hinge 110, and the third housing 103 and the second housing 102 are freely pivotally connected to each other via a second hinge 111. The first hinge 110 is provided between the first housing 101 and the third housing 103, and the second hinge 111 is provided between the third housing 103 and the second housing 102. A first circuit board 105 provided in the first housing 101 and a second circuit board 106 provided in the second housing 102 are connected to each other vie a signal cable 120. A small-diameter wire coaxial cable is mainly used as the signal cable 120.

FIG. 15 is a view showing a configuration of a connection portion between the second housing 102 and the third housing 103. In this figure, a connector 121 is connected to one end of the signal cable 120, and the connector 121 is connected to a connector 122 mounted on the second circuit board 106. Another identical connector 121 (not shown) is also connected to the other end of the signal cable 120 and the connector 121 is connected to a connector 122 (not shown) mounted on the first circuit board 105 in the first housing 101. The second housing 102 is provided therein with a plate-shaped member 130 to compensate a strength reduction of the second housing 102 due to a thinned device body and an enlarged liquid crystal display 140 (see FIG. 14(a)). The plate-shaped member 130 is mainly made of a stainless steel having stiffness.

A side of the plate-shaped member 130 located toward the second hinge 111 is provided with a notch 131 for allowing the signal cable 120 to be passed therethrough. The notch 131 of the plate-shaped member 130 is intended to allow the signal cable 120 to be naturally extended through a cylindrical portion of the second hinge 111. Specifically, the first hinge 111 is located at the approximately middle of the second housing 102 and the second circuit board 106 is disposed adjacent to a back surface (i.e., a surface opposite to a surface provided with the liquid crystal display 104) inside the second housing 102, and therefore a stepped portion is created between the second hinge 111 and the plate-shaped member 130. As a result of the stepped portion, the signal cable 120 needs to be bent at approximately a right angle at an end of the plate-shaped member 130 located toward the second hinge 111, if the plate-shaped member 130 is not provided with the notch 131. Accordingly, it is possible to impose a load in terms of strength on the signal cable 120, thereby causing a failure, such as a broken wire. Therefore, the plate-shaped member 130 is provided with the notch 131, so that the signal cable 120 can be extended through the cylindrical portion of the second hinge 111 without the signal cable 120 placed in the loaded state.

### CITATION LIST

### Patent Documents

[Patent Document 1] JP-A-2006-005567

[Patent Document 2] JP-A-2009-111914

### SUMMARY OF THE INVENTION

### Problems to be Solved by the Invention

However, downsizing and thinning is highly demanded for mobile phones, which is one type of mobile wireless devices, in terms of design ability. In particular, when the two-axis rotation structure is employed, it is significant to achieve coexistence between thinning and strengthening and also to ensure antenna performance with the coexistence achieved. One method for thinning the mobile wireless device having the two-axis rotation structure is that the second hinge 111 is provided on a lower side of the second housing 102 as described above. One method for strengthening is that the plate-shaped member 130 is provided as described above. Also, the plate-shaped member 130 needs to be provided with the notch 131 for the purpose of thinning. However, when an antenna is disposed near the hinge portion, an antenna current is concentrated on a lower end portion 150 of the plate-shaped member 130. Therefore, if the notch 131 is provided, the antenna current flows along ends of the notch 131, thereby causing an unnecessary resonance. In addition, the signal cable 120 which would otherwise be covered with the plate-shaped member 130 is exposed in the notch 131, thereby increasing an unnecessary emitting from the signal cable 120.

Also, by forming the notch 131 on the plate-shaped member 130, the connector 121 is disposed in front of the notch 131, i.e., on an upper end side (a lower side in FIG. 15) of the second housing 102, thereby extending a routing length of the signal cable 120 inside the second housing 102. This also causes deterioration in antenna performance.

As described above, when the antenna is disposed near the second hinge 111, the notch 131 of the plate-shaped member 130 and the extended routing length of the signal cable 120 are influenced on the antenna performance. Meanwhile, the influence on the antenna performance can likewise be caused in typical foldable mobile wireless devices, if the mobile wireless devices have a hinge for freely openably and closably connecting a first housing with a second housing and an antenna thereof is disposed near the hinge.

Accordingly, the present invention has been made keeping in mind the above problems, and an object of the present invention is to provide a mobile wireless device in which, even if thinning and strengthening of a device body are simultaneously performed, the influences on antenna performance due to a notch of a plate-shaped member for strengthening and due to routing of a signal cable for electrically connecting a first circuit board with a second circuit board can be reduced, thereby achieving high antenna performance.

### Means for Solving the Problems

A mobile wireless device according to the present invention includes a first housing, a second housing, a first hinge configured to freely openably and closably connect the first housing with the second housing, a first circuit board provided in the first housing, a second circuit board provided in the second housing, a signal cable configured to electrically connect the first circuit board with the second circuit board, a plate-shaped ground that is provided so as to be stacked on the second circuit board and has a notch at a location through which the signal cable is passed, and a conductive member that covers the signal cable and the notch.

According of this configuration, the conductive member covers the signal cable and the notch of the plate-shaped ground, so that, even if an antenna is disposed near the hinge for freely openably and closably connecting the first housing with the second housing, the influence of the notch of the plate-shaped ground or the influence of routing of the signal cable for electrically connecting the first circuit board with the second circuit board can be reduced, thereby achieving high antenna performance.

A mobile wireless device according to the present invention includes a first housing, a second housing, a third housing, a first hinge configured to freely openably and closably connect the first housing with the third housing, a second hinge configured to freely pivotally connect the second housing with the third housing, a first circuit board provided in the first housing, a second circuit board provided in the second housing, a signal cable configured to electrically connect the first circuit board with the second circuit board, a plate-shaped ground that is provided so as to be stacked on the second circuit board and has a notch at a location through which the signal cable is passed, and a conductive member that covers the signal cable and the notch.

According to this configuration, the conductive member covers the signal cable and the notch of the plate-shaped ground, so that, even if an antenna is disposed near the hinge for freely openably and closably connecting the first housing with the third housing, the influence of the notch of the plate-shaped ground or the influence of routing of the signal cable for electrically connecting the first circuit board with the second circuit board can be reduced, thereby achieving high antenna performance.

In the above configurations, the conductive member is capacitively coupled to the plate-shaped ground around the notch.

According to this configuration, because the conductive member is capacitively coupled to the plate-shaped ground around the notch, the influence of the notch on the signal cable can be reduced, thereby achieving high antenna performance.

In the above configurations, the conductive member is electrically connected to the plate-shaped ground.

According to this configuration, because the conductive member is electrically connected to the plate-shaped ground, the influence of the notch on the signal cable can be reduced, thereby achieving high antenna performance.

In the above configurations, the conductive member has a protrusion on a surface thereof which covers the signal cable.

According to this configuration, the capacitive coupling between the conductive member and the signal cable can be strengthened, and the influence of the notch on the signal cable can be further reduced, thereby achieving more high antenna performance. In particular, because the more the number of protrusions, the stronger the coupling is, the effect of such measures can be further enhanced.

In the above configurations, the first hinge is used as an antenna device.

According of this configuration, the conductive member covers the signal cable and the notch of the plate-shaped ground, so that, even if the first hinge is used as an antenna device, the influence of the notch of the plate-shaped ground, the influence of the notch on the signal cable, or the influence of routing of the signal cable for electrically connecting the first circuit board with the second circuit board can be reduced, thereby achieving high antenna performance.

### Advantageous Effects of the Invention

According to the present invention, high antenna performance can be achieved even if thinning and strengthening of a device body are simultaneously performed.

### BRIEF DESCRIPTION OF DRAWINGS

FIG. 1 is a view showing a configuration of a connection portion between a second housing and a third housing in a mobile wireless device according to an embodiment 1 of the present invention.

FIG. 2 is a sectional view taken along a line A-A in FIG. 1.

FIG. 3 is a sectional view taken along a line B-B in FIG. 1.

FIG. 4 is a view showing a configuration of a connection portion between a second housing and a third housing in a mobile wireless device according to an embodiment 2 of the invention.

FIG. 5 is a sectional view showing a portion on which a conductive member is attached in a mobile wireless device according to an embodiment 3 of the invention.

FIG. 6 is a view showing a configuration of a connection portion between a second housing and a third housing in a mobile wireless device according to an embodiment 4 of the invention.

FIG. 7 is a sectional view taken along a line C-C in FIG. 6.

FIG. 8 is a sectional view showing a portion on which a conductive member is attached in a mobile wireless device according to an embodiment 5 of the invention.

FIG. 9 is a view showing a configuration of a connection portion between a second housing and a third housing in a mobile wireless device according to an embodiment 6 of the invention.

FIG. 10 is a sectional view taken along a line D-D in FIG. 9.

FIG. 11 is a view showing a configuration of a connection portion between a second housing and a third housing in a mobile wireless device according to an embodiment 7 of the invention.

FIGS. 12(a) and 12(b) are perspective views showing the exterior of a mobile wireless device according to an embodiment 8 of the invention.

FIG. 13 is a view showing a configuration of a connection portion between a second housing and a third housing in the mobile wireless device of FIG. 12.

FIGS. 14(a) and 14(b) are perspective views showing the exterior of a foldable mobile wireless device employing a two-axis rotation structure.

FIG. 15 is a view showing a configuration of a connection portion between a second housing and a third housing in the mobile wireless device of FIG. 14.

### DESCRIPTION OF EMBODIMENTS

Preferred embodiments for implementing the present invention will be now described in detail with reference to the accompanying drawings.

### Embodiment 1

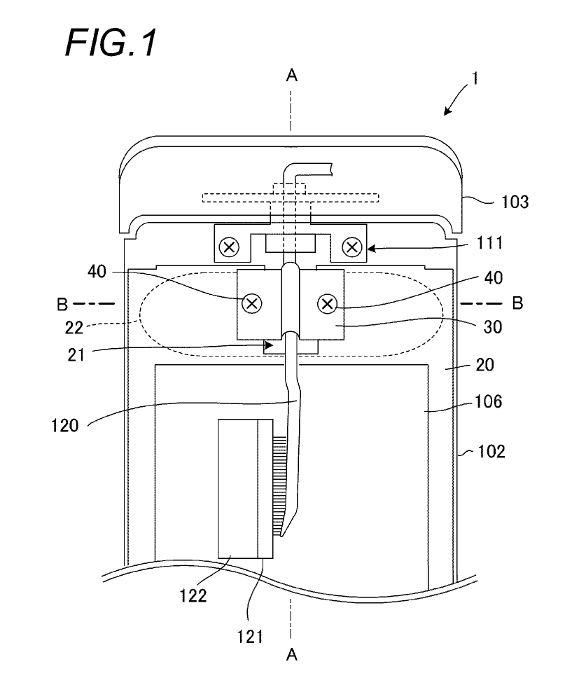

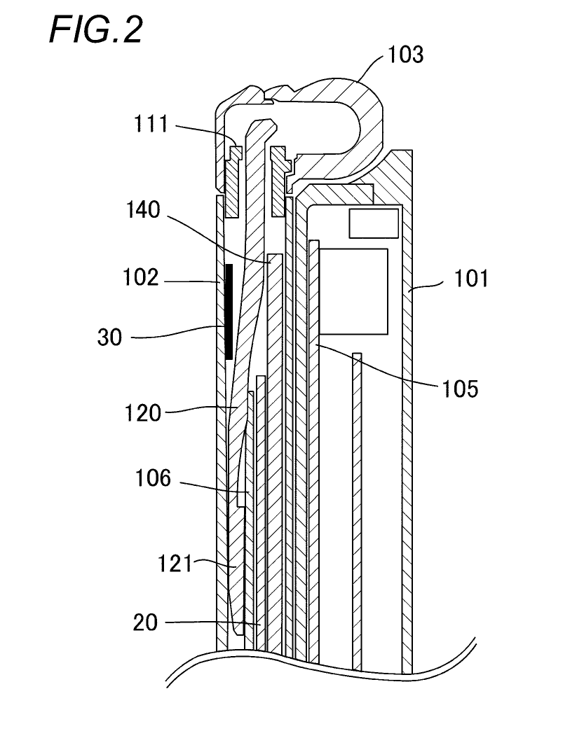

FIG. 1 is a view showing a configuration of a connection portion between a second housing and a third housing in a mobile wireless device according to an embodiment 1 of the present invention. FIG. 2 is a sectional view taken along a line A-A in FIG. 1.

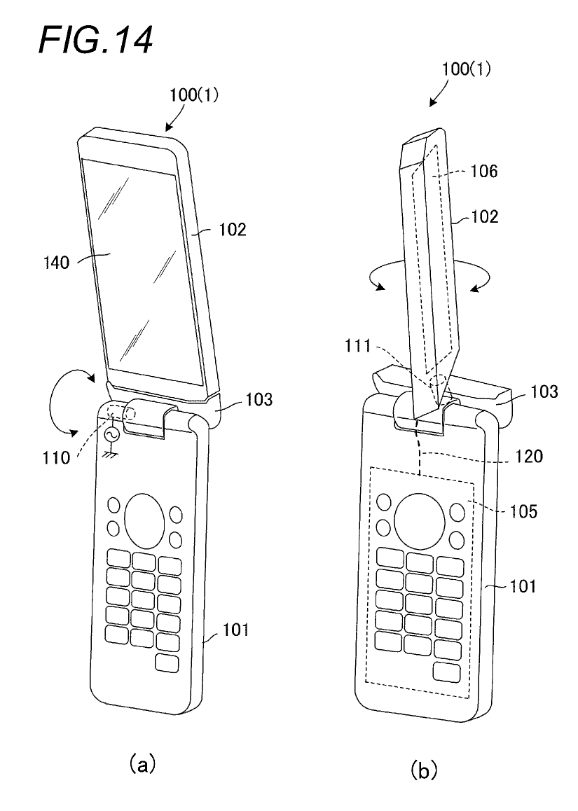

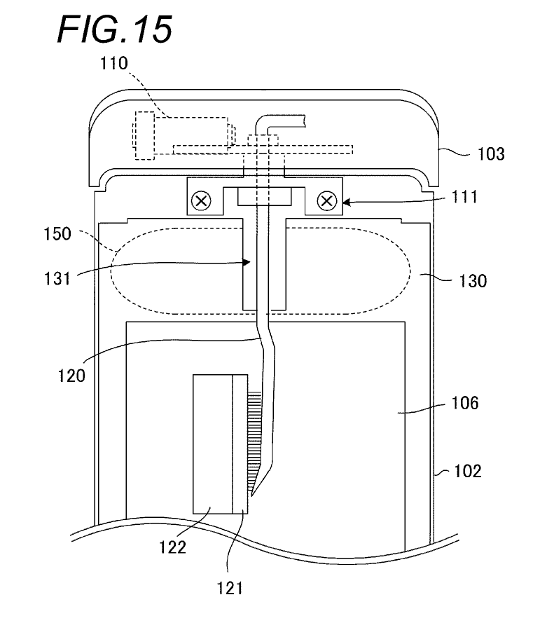

The mobile wireless device of the present embodiment is a foldable type employing the same two-axis rotation structure as that of a mobile wireless device according to the related art in FIGS. 14(a) and 14(b). The entire configuration is the same as that of FIGS. 14(a) and 14(b), and accordingly will be described with reference to FIGS. 14(a) and 14(b). However, the mobile wireless device of the embodiment is designated as a reference numeral ‘1’.

As shown in FIGS. 14(a) and 14(b), the mobile wireless device 1 of the embodiment includes a first housing 101, a second housing 102, and a third housing 103. The first housing 101 and the third housing 103 are freely openably and closably connected to each other via a first hinge 110. The third housing 103 and the second housing 102 are freely pivotally connected to each other via a second hinge 111. The first hinge 110 is provided between the first housing 101 and the third housing 103, and the second hinge 111 is provided between the third housing 103 and the second housing 102. A first circuit board 105 provided in the first housing 101 and a second circuit board 106 provided in the second housing 102 are connected to each other vie a signal cable 120.

In FIG. 1, the second housing 102 is provided therein with a plate-shaped ground 20 stacked on the second circuit board 120 to compensate a strength reduction of the second housing 102 due to a thinned device body and an enlarged liquid crystal display 140 (see FIG. 14(a)), and a side of the plate-shaped ground 20 located toward the second hinge 111 is provided with a notch 21 for allowing the signal cable 120 to be extended therethrough. The plate-shaped ground 20 is identical to the plated shaped member 130 in the related art and is mainly made of a stainless steel having stiffness.

The notch 21 of the plate-shaped ground 20 is intended to allow the signal cable 120 to be naturally extended through a cylindrical portion of the second hinge 111 with respect to a stepped portion created between the second hinge 111 and the plate-shaped ground 20. However, when an antenna device (not shown) is disposed near the second hinge 111, an antenna current is likely to be distorted in a lower end 22 of the plate-shaped ground 20 due to providing the notch 21, thereby deteriorating antenna performance. In particular, the antenna current is concentrated on the lower end 22 of the plate-shaped ground 20, thereby increasing deterioration in antenna performance.

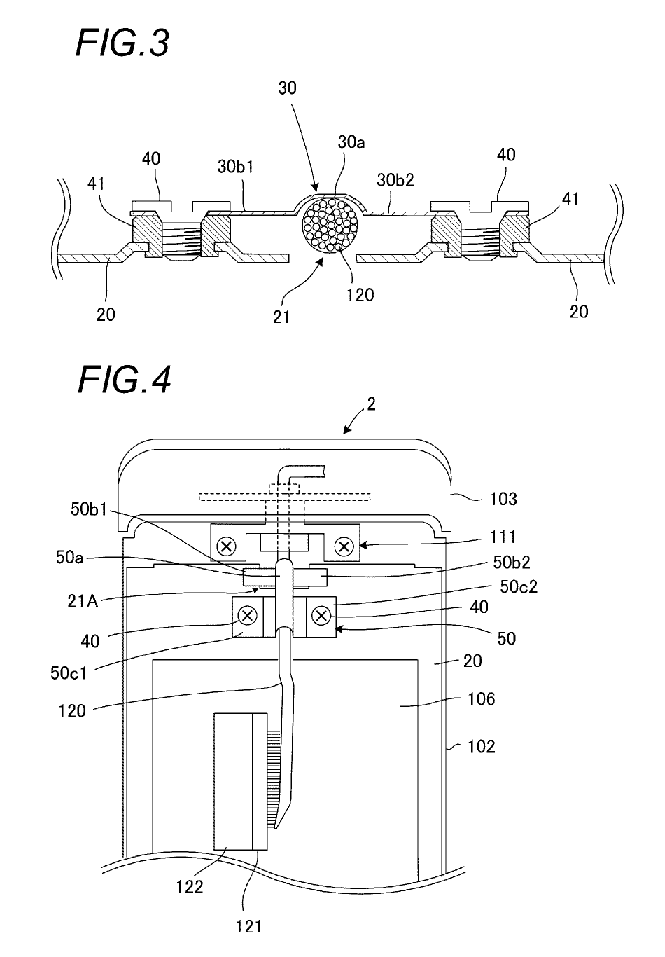

According to the invention, a member having an electrical conductivity covers the signal cable 120 and the notch 21 of the plate-shaped ground 20, so that the distortion of the antenna current in the lower end 22 of the plate-shaped ground 20 is limited to be low. In the mobile wireless device 1 of the embodiment, a plate-shaped conductive member 30 having a semi-cylindrical portion 30a (see FIG. 3) at the center portion thereof as shown in FIG. 1 is used as such a member having an electrical conductivity. The conductive member 30 is sized to cover the approximately entire area of the notch 21 of the plate-shaped ground 20.

FIG. 3 is a sectional view taken along a line B-B in FIG. 1. As shown in the figure, the conductive member 30 is constituted of the semi-cylindrical portion 30a and extension portions 30b1 and 30b2 integrally formed with the semi-cylindrical portion 30a and perpendicularly extended from each of both sides of the semi-cylindrical portion 30a. The semi-cylindrical portion 30a is sized to be covered around and hide a part of an outer conductor of the signal cable 120. The extension portions 30b1 and 30b2 are sized to cover the notch 21 of the ground 20 in combination with the semi-cylindrical portion 30a. The conductive member 30 is fixed on the plate-shaped ground 20 by the extension portions 30b1 and 30b2. In this time, screws 40 and 40 are used to fix the conductive member 30. On the other hands, the plate-shaped ground 20 is provided with screw receiving portions 41, and thus the conductive member 30 is fixed on the plate-shaped ground 20 by the screw receiving portions 41 and the screws 40.

The signal cable 120 is covered with the semi-cylindrical portion 30a of the conductive member 30, so that the semi-cylindrical portion 30a is capacitively coupled to the outer conductor of the signal cable 120 and the outer conductor of the signal cable 120 is high-frequency connected to the ground. Also, the notch 21 of the plate-shaped ground 20 is covered with the whole of the conductive member 30, so that, even if the antenna device (not shown) is disposed near the first hinge 110 or the second hinge 111, the influence of the notch 21 of the plate-shaped ground 20 or the influence of routing of the signal cable 120 can be reduced, thereby achieving high antenna performance.

As described above, according to the mobile wireless device of the present embodiment, the conductive member 30 is provided to cover the signal cable 120 electrically connecting the first circuit board 105 provided in the first housing 101 with the second circuit board 105 provided in the second housing 102 and to cover the notch 21 of the plate-shaped ground 20 provided to be stacked on the second circuit board 106. As a result, the influence of the notch 21 of the plate-shaped ground 20 or the influence of routing of the signal cable 120 can be reduced even if the antenna device is disposed near the first hinge 110, thereby achieving high antenna performance.

### Embodiment 2

FIG. 4 is a view showing a configuration of a connection portion between a second housing and a third housing in a mobile wireless device according to an embodiment 2 of the invention. The mobile wireless device 2 according to the present embodiment employs a two-axis rotation structure, like the mobile wireless device 1 of the foregoing embodiment 1.

The mobile wireless device 2 of the present embodiment includes a conductive member 50 adapted to a notch 21A smaller than the notch 21 of the mobile wireless device 1 of the foregoing embodiment 1. The conductive member 50 is constituted of a semi-cylindrical portion 50a, wing portions 50b1 and 50b2 perpendicularly extended from each of both sides of one end portion of the semi-cylindrical portion 50a, and extension portions 50c1 and 50c2 perpendicularly extended from each of both sides of the other end portion of the semi-cylindrical portion 50a, and the wing portions 50b1 and 50b2 and the extension portions 50c1 and 50c2 are integrally formed with the semi-cylindrical portion 50a. The semi-cylindrical portion 50a is sized to be covered around and hide a part of an outer conductor of the signal cable 120, and the wing portions 50b1 and 50b2 are sized to cover the notch 21A of a plate-shaped ground 20. The extension portions 50c1 and 50c2 are intended to fix the conductive member 50 on the plate-shaped ground 20. The conductive member 50 is fixed on the plate-shaped ground 20 by screws 40 and 40.

By fixing the conductive member 50 on the plate-shape ground 20, the wing portions 50b1 and 50b2 are covered over the notch 21A of the plate-shaped ground 20 and the semi-cylindrical portion 50a is covered around the part of the outer conductor of the signal cable 120, so that, even if an antenna device is disposed near the first hinge 110, the influence of the notch 21A of the plate-shaped ground 20 or the influence of routing of the signal cable 120 can be reduced, thereby achieving high antenna performance.

### Embodiment 3

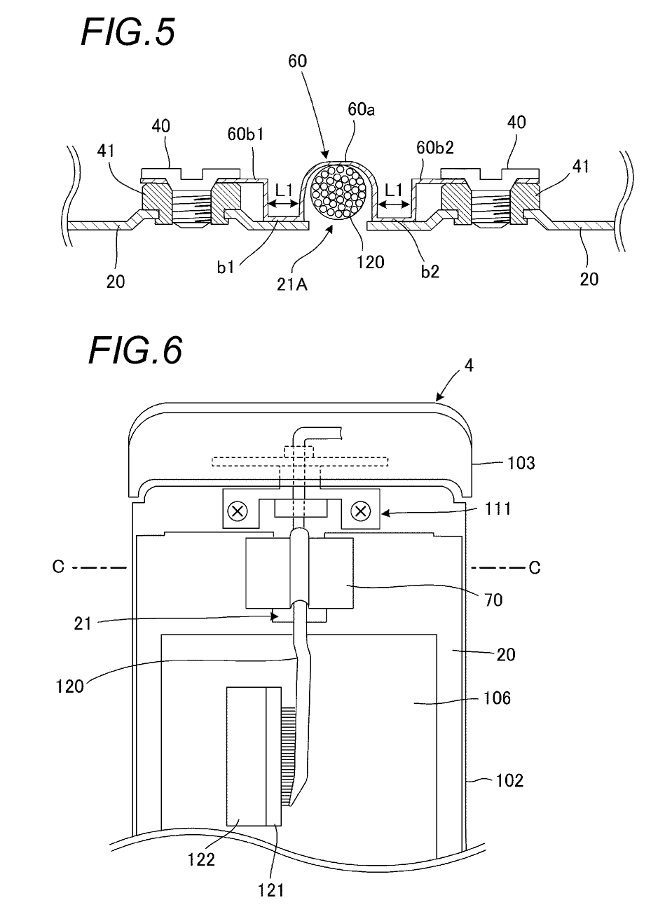

FIG. 5 is a sectional view showing a portion on which a conductive member is attached in a mobile wireless device according to an embodiment 3 of the invention. FIG. 5 is the same as the sectional view taken along the line B-B in FIG. 1 as shown in FIG. 3. The mobile wireless device 3 according to the present embodiment employs a two-axis rotation structure, like the mobile wireless device 1 of the foregoing embodiment 1.

In FIG. 5, a conductive member 60 of the mobile wireless device 2 according to the present embodiment is constituted of a semi-cylindrical portion 60a and extension portions 60b1 and 60b2, like the conductive member 30 of the mobile wireless device 1 according to the foregoing embodiment 1, but is different in that portions b1 and b2 of each of the extension portions 60b1 and 60b2 located toward the semi-cylindrical portion 60a are formed to have a concave cross section to be capacitively coupled to an end of a notch 21A of a plate-shaped ground 20. By coupling the conductive member 60 to the plate-shaped ground 20 using the portions b1 and b2, the coupling between an outer conductor of the signal cable 120 and the plate-shaped ground 20 is strengthened. Meanwhile, the size of the notch of the plate-shaped ground 20 in the present embodiment is approximately equal to that of the notch 21A of the embodiment 2, but even if the notch is larger or smaller, the portions b1 and b2 of the extension portions 60b1 and 60b2 can be adapted to the notch by adjusting a length L1 thereof.

As described above, by fixing the conductive member 60 on the plate-shape ground 20, the semi-cylindrical portion 60a of the conductive member 60 is covered over the notch 21A of the plate-shaped ground 20 and also covered around the part of the outer conductor of the signal cable 120, so that, even if an antenna device is disposed near the first hinge 110, the influence of the notch 21A of the plate-shaped ground 20 or the influence of routing of the signal cable 120 can be reduced, thereby achieving high antenna performance. In particular, the outer conductor of the signal cable 120 can be rigidly coupled to the plate-shaped ground 20, thereby further decreasing such influences.

### Embodiment 4

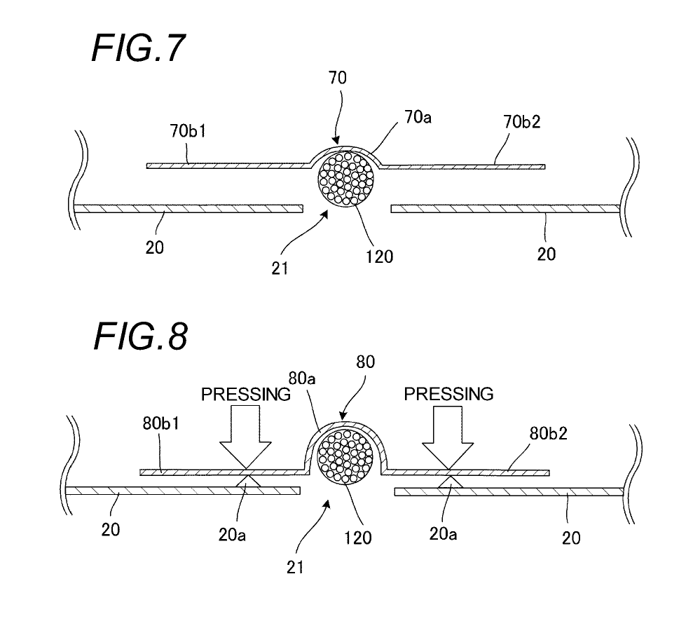

FIG. 6 is a view showing a configuration of a connection portion between a second housing and a third housing in a mobile wireless device according to an embodiment 4 of the invention. FIG. 7 is a sectional view taken along a line C-C in FIG. 6. The mobile wireless device 4 according to the present embodiment employs a two-axis rotation structure, like the mobile wireless device 1 of the foregoing embodiment 1.

In FIG. 6, the mobile wireless device 4 according to the present embodiment has a conductive member 70 having the approximately same shape as that of the conductive member 30 according to the foregoing embodiment 1 and constituted of a semi-cylindrical portion 70a and extension portions 70b1 and 70b2. The mobile wireless device 4 of the present embodiment is different from the conductive member 30 of the embodiment 1 in that, although the conductive member 30 in the embodiment 1 is fixed on the plate-shaped ground 20 by screw clamping, the conductive member 70 in the mobile wireless device 4 of the present embodiment is fixed on an inner wall surface (not shown) of the second housing 102 (see FIGS. 4(a) and (b)). In this case, the fixation of the conductive member 70 to the inner wall surface of the second housing 102 can be achieved by a method of screw clamping with a spacer interposed therebetween or by a method of securing by means of an adhesive tape or glue with a spacer interposed therebetween as well.

As described above, the conductive member 70 is connected to the plate-shaped ground 20 by a capacitive coupling. Meanwhile, the narrower the gap between the conductive member 70 and the plate-shaped ground 20, the stronger the capacitive coupling between both is. The conductive member 70 is covered over a notch 21 of the plate-shaped ground 20 and also covered around a part of an outer conductor of the signal cable 120, so that, even if an antenna device is disposed near the first hinge 110, the influence of the notch 21 of the plate-shaped ground 20 or the influence of routing of the signal cable 120 can be reduced, thereby achieving high antenna performance.

### Embodiment 5

FIG. 8 is a sectional view showing a portion on which a conductive member is attached in a mobile wireless device according to an embodiment 5 of the invention. The figure is the same as the sectional view taken along the line B-B in FIG. 1 as shown in FIG. 3. The mobile wireless device according to the present embodiment employs a two-axis rotation structure, like the mobile wireless device 1 of the foregoing embodiment 1.

In FIG. 8, a conductive member 80 of the mobile wireless device of the present embodiment is the approximately same as the conductive member 30 of the mobile wireless device 1 of the foregoing embodiment 1 and is constituted of a semi-cylindrical member 80a and extension portions 80b1 and 80b2, but the semi-cylindrical member 80a is curved to be deeper than the semi-cylindrical member 30 of the mobile wireless device 1 of the embodiment 1, thereby having a shape able to cover more than half the circumference of an outer conductor of the signal cable 120. Meanwhile, a plate-shaped ground 20 is provided with protrusions 20a and 20a each having a sharp tip on a surface thereof opposed to each of the extension portions 80b1 and 80b2 of the conductive member 80 to be positively contacted with the extension portions 80b1 and 80b2 of the conductive member 80. The extension portions 80b1 and 80b2 of the conductive member 80 is urged from an inner wall surface (not shown) of the second housing 102 (see FIGS. 14(a) and 14(b)) toward the plate-shaped ground 20 by an elastic body, such as a spring or a cushion.

As described above, the conductive member 80 is connected to the plate-shaped ground 20 by direct and capacitive couplings. The conductive member 80 is covered over a notch 21 of the plate-shaped ground 20 and also covered around a part of the outer conductor of the signal cable 120, so that, even if an antenna device is disposed near the first hinge 110, the influence of the notch 21 of the plate-shaped ground 20 or the influence of routing of the signal cable 120 can be reduced, thereby achieving high antenna performance.

### Embodiment 7

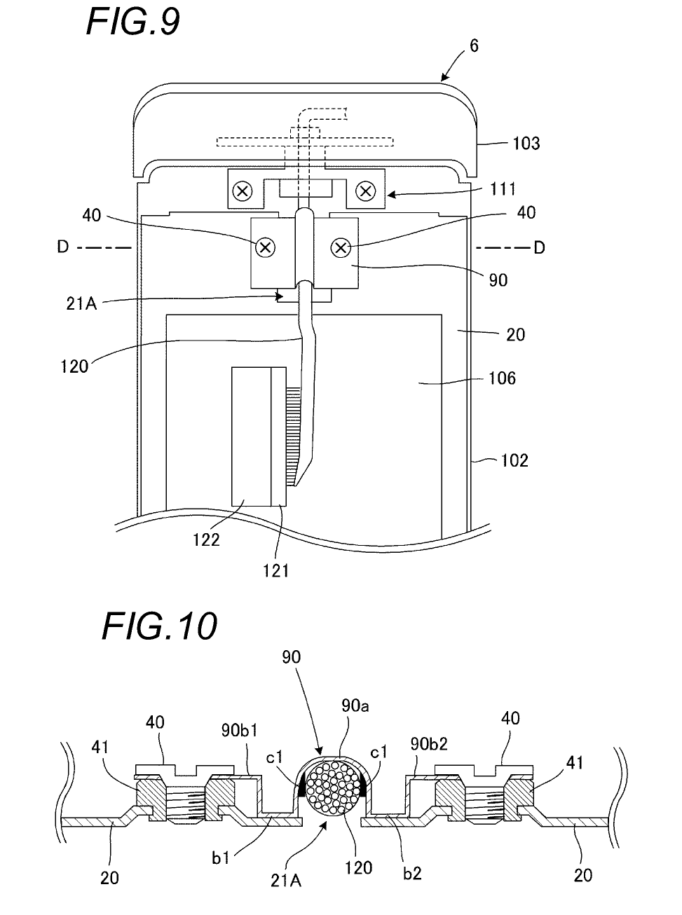

FIG. 9 is a view showing a configuration of a connection portion between a second housing and a third housing in a mobile wireless device according to an embodiment 6 of the invention. FIG. 10 is a sectional view taken along a line D-D in FIG. 9. The mobile wireless device 6 according to the present embodiment employs a two-axis rotation structure, like the mobile wireless device 1 of the foregoing embodiment 1.

In FIGS. 9 and 10, a conductive member 90 of the mobile wireless device 6 according to the present embodiment is constituted of a semi-cylindrical portion 90a and extension portions 90b1 and 90b2 respectively having portions b1 and b2, which is located toward the semi-cylindrical portion 90a and formed to have a concave cross section, like the conductive member 60 of the mobile wireless device according to the foregoing embodiment 3, but is different in that the semi-cylindrical portion 90a covering the signal cable 120 has at least two protrusions c1 formed on an inner surface thereof to strengthen a capacitive coupling with the signal cable 120. By strengthening the capacitive coupling between the conductive member 90 and an outer conductor of the signal cable 120, the coupling between the outer conductor of the signal cable 120 and the plate-shaped ground 20 is strengthened. In this case, the more the number of protrusions c1, the stronger the coupling is. As a result, the influence of the notch 21A of the plate-shaped ground 20 or the influence of routing of the signal cable 120 can be further reduced even if an antenna device is disposed near the first hinge 110, thereby achieving more high antenna performance.

### Embodiment 7

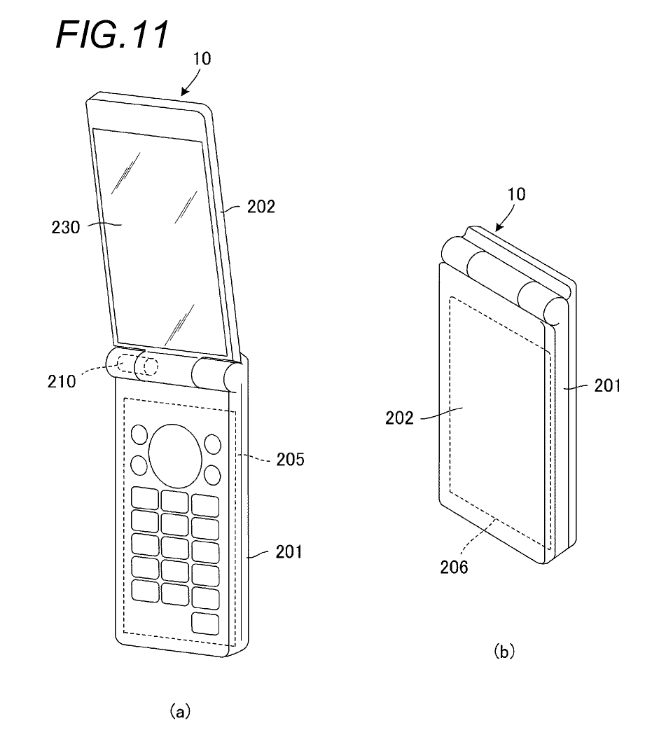

FIG. 11 is a view showing a configuration of a connection portion between a second housing and a third housing in a mobile wireless device according to an embodiment 7 of the invention. The mobile wireless device 7 according to the present embodiment employs a two-axis rotation structure, like the mobile wireless device 1 of the foregoing embodiment 1. Also, the mobile wireless device 7 of the present embodiment includes the same conductive member 90 as that of the foregoing embodiment 6.

In particular, the mobile wireless device 7 of the present embodiment employs the first hinge 110 as an antenna device. Even if the first hinge 110 is used as the antenna device,

the conductive member 90 is covered over a notch 21A of a plate-shaped ground 20 and also covered around a part of an outer conductor of the signal cable 120, so that the influence of the notch 21A of the plate-shaped ground 20 or the influence of routing of the signal cable 120 can be reduced, thereby achieving high antenna performance.

### Embodiment 8

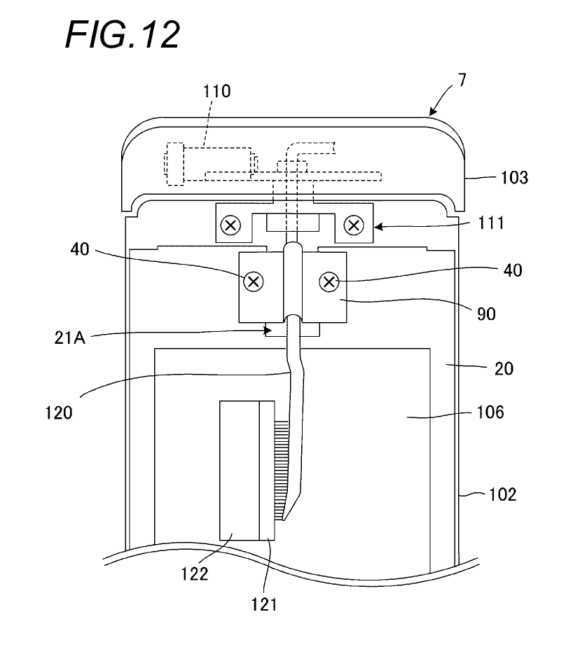

FIG. 12 shows perspective views of the exterior of a mobile wireless device according to an embodiment 8 of the invention. In this figure, (a) shows an opened state and (b) shows a closed state. The mobile wireless device 10 of the present embodiment includes two housings (i.e., a first housing 201 and a second housing 202), and the first housing 201 and the second housing 202 are freely openably and closably connected to each other via a hinge (i.e., a first hinge) 210. The hinge 210 is provided between the first housing 201 and the second housing 202.

A first circuit board 205 is provided in the first housing 201 and a second circuit board 206 is provided in the second housing 202.

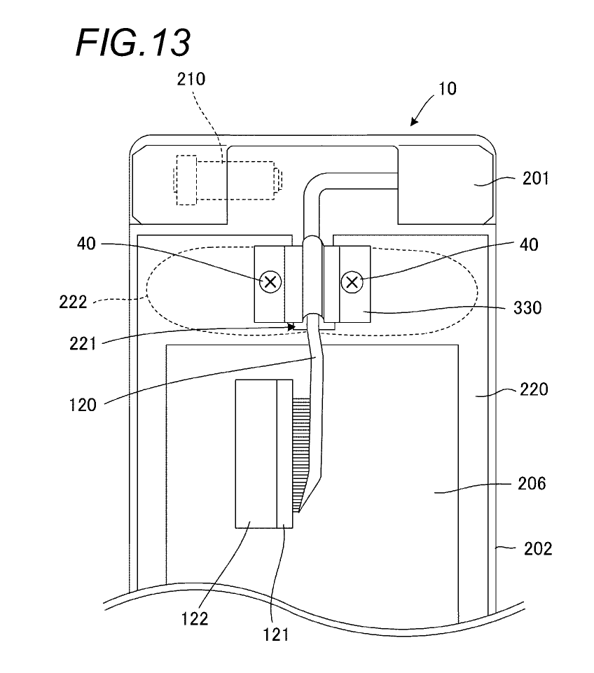

FIG. 13 is a view showing a configuration of a connection portion between the first housing 201 and the second housing 202 in the mobile wireless device 10 according to the present embodiment. In FIG. 13, the first circuit board 205 provided in the first housing 201 and the second circuit board 206 provided in the second housing 202 are connected to each other vie a signal cable 120.

Likewise, in the mobile wireless device 10 of the present embodiment, the second housing 202 is provided therein with a plate-shaped ground 220 adapted to compensate a strength reduction of the second housing 202 due to a thinned device body and an enlarged liquid crystal display 230, and a side of the plate-shaped ground 220 located toward the hinge 210 is provided with a notch 221 for allowing the signal cable 120 to be extended therethrough. The plate-shaped ground 220 is mainly made of a stainless steel having stiffness.

The mobile wireless device 10 of the present embodiment includes a conductive member 330 having the same shape as that of the conductive member 60 of the mobile wireless device of the foregoing embodiment 3, and the conductive member 330 is covered over the notch 221 of the plate-shaped ground 220 and also covered around a part of an outer conductor of the signal cable 120, so that, even if an antenna device is disposed near the hinge 210 or the hinge 210 itself is used as the antenna device, the influence of the notch 221 of the plate-shaped ground 220 or the influence of routing of the signal cable 120 can be reduced, thereby achieving high antenna performance.

Although the conductive members 30, 50, 60, 80, 90 and 330 are fixed on the plate-shaped grounds 20 and 220 in the embodiments 1 to 3 and 5 to 8 other than the embodiment 4, the conductive member 70 may be fixed on the inner wall surface of the second housing 102 as in the embodiment 4.

Also, although the plate-shaped ground 20 is provided with protrusions 20a in the embodiment 5, the same protrusions 20a may be also provided on the plate-shaped grounds 20 and 220 in the other embodiments 1 to 4 and 6 to 8.

In addition, although the first hinge 110 is used as the antenna device in the embodiment 7, the first hinge 110 (the hinge 210 in the embodiment 8) may be also used as the antenna device in the other embodiments 1 to 6 and 8.

Although the present invention has been described in detail and with reference to a specific embodiment, it will be apparent by those skilled in the art that various changes and modifications may be made without departing from the spirit and scope of the invention.

This application is based on Japanese Patent Application (Japanese Patent Application No. 2010-153435) filed on Jul. 5, 2010, the entire contents of which are incorporated herein by reference.

### INDUSTRIAL APPLICABILITY

The present invention can be applied to mobile wireless devices, such as foldable mobile phones, PHSs (Personal Handy-Phone Systems), smart phones, handheld game consoles, note-type personal computers.

### DESCRIPTION OF REFERENCE NUMERALS AND SIGNS

1, 2, 4, 6, 7, 10 Mobile wireless device
20, 220 Plate-shaped ground
21, 21A, 221 Notch
30, 50, 60, 70, 80, 90, 330 Conductive member
30a, 50a, 60a, 70a, 80a, 90a Semi-cylindrical portion
30b1, 30b2, 50c1, 50c2, 60b1, 60b2, 70b1, 70b2, 80b1, 80b2, 90b1, 90b2 Extension portion
40 Screw
41 Screw receiving portion
50b1, 50b2 Wing portion
101, 201 First housing
102, 202 Second housing
103 Third housing
105, 205 First circuit board
106, 206 Second circuit board
110 First hinge
111 Second hinge
120 Signal cable
121, 122 Connector
140, 230 Liquid crystal display
210 Hinge

1. A mobile wireless device comprising:
a first housing;
a second housing;
a first hinge configured to freely openably and closably connect the first housing with the second housing;
a first circuit board provided in the first housing;
a second circuit board provided in the second housing;
a signal cable configured to electrically connect the first circuit board with the second circuit board;
a plate-shaped ground that is provided so as to be stacked on the second circuit board and has a notch at a location through which the signal cable is passed; and
a conductive member that covers the signal cable and the notch.

2. A mobile wireless device comprising:
a first housing;
a second housing;
a third housing;
a first hinge configured to freely openably and closably connect the first housing with the third housing;
a second hinge configured to freely pivotally connect the second housing with the third housing;
a first circuit board provided in the first housing;
a second circuit board provided in the second housing;
a signal cable configured to electrically connect the first circuit board with the second circuit board;
a plate-shaped ground that is provided so as to be stacked on the second circuit board and has a notch at a location through which the signal cable is passed; and
a conductive member that covers the signal cable and the notch.

3. The mobile wireless device according to claim 1, wherein the conductive member is capacitively coupled to the plate-shaped ground around the notch.

4. The mobile wireless device according to claim 1, wherein the conductive member is electrically connected to the plate-shaped ground.

5. The mobile wireless device according to claim 1, wherein the conductive member has a protrusion on a surface thereof which coves the signal cable.

6. The mobile wireless device according to claim 1, wherein the first hinge is used as an antenna device.

7. The mobile wireless device according to claim 2, wherein the conductive member is capacitively coupled to the plate-shaped ground around the notch.

8. The mobile wireless device according to claim 2, wherein the conductive member is electrically connected to the plate-shaped ground.

9. The mobile wireless device according to claim 2, wherein the conductive member has a protrusion on a surface thereof which coves the signal cable.

10. The mobile wireless device according to claim 2, wherein the first hinge is used as an antenna device.
